(19) United States
(12) Patent Application Publication
(10) Pub. No.: US 2008/0117589 A1
(43) Pub. Date: May 22, 2008

(54) Self Adjusting Air Directing Baffle

(75) Inventors: Jaime A. Carrera, Austin, TX (US); Robert Lloyd Riegler, Austin, TX (US)

Correspondence Address: HAYNES AND BOONE, LLP, 901 Main Street, Suite 3100, Dallas, TX, 75202, US

(73) Assignee: DELL PRODUCTS L.P., Round Rock, TX (US)

(21) Appl. No.: 11/562,497

(22) Filed: Nov. 22, 2006

(51) Int. Cl. H05K 7/20; F24F 7/00

(52) U.S. Cl. 361/687; 165/59

(57) ABSTRACT

An air directing apparatus includes a base defining a component housing. A baffle member is moveably coupled to the base and operable to move into and out of the component housing such that the baffle member may engage a component located in the component housing. An air directing member is located on the baffle member, whereby the air directing member is operable to direct an airflow towards a high heat producing feature on the component when the baffle member engages the component. The apparatus may be located adjacent connectors in a chassis that may either be empty or include components such that airflow from a fan is blocked past empty connectors and directed towards high heat producing features on components that are located in connectors.

### BACKGROUND

The present disclosure relates generally to information handling systems, and more particularly to a self adjusting air directing baffle in an information handling system chassis.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Some IHSs include a plurality of components such as, for example, Dual Inline Memory Modules (DIMMs), that couple to the IHS through a plurality of adjacent connectors. As the power of these components continues to increase, the cooling of the components becomes an issue.

Typically, fans are placed adjacent the components in order to provide an airflow over the components in order to convectively cool them. However, sometimes not all of the adjacent connectors in the IHS are filled with components, and the volume above the empty connectors provides an air bypass that can result in a non-optimal airflow past the components that are in the connectors such that the components performance is reduced. Furthermore, some components such as, for example, DIMMs, may include high heat producing features such as, for example, Advanced Memory Buffers (AMBs), that require more cooling than the rest of the component.

Conventional solutions include providing blanks in the connectors which do not have a component coupled to them in order to block airflow past the empty components and increase the airflow past the components that are coupled to the connectors. This helps when a connector does not have a component coupled to it, but in the situation where the components are of different sizes, an air bypass may still be provided over the top of smaller components that prevents the optimal cooling of the components. Also, coupling each blank to each connector that does not include a component is a time consuming process that increases the manufacturing time for the information handling and raises costs. Furthermore, such solutions do nothing to address the increased cooling needs of the high heat producing features on the component.

Accordingly, it would be desirable to provide an air directing apparatus absent the disadvantages found in the prior methods discussed above.

### SUMMARY

According to one embodiment, an air directing apparatus includes a base defining a component housing, a baffle member moveably coupled to the base and operable to move into and out of the component housing such that the baffle member may engage a component located in the component housing, and an air directing member located on the baffle member, whereby the air directing member is operable to direct an airflow towards a high heat producing feature on the component when the baffle member engages the component.

### BRIEF DESCRIPTION OF THE DRAWINGS

FIG. 1 is a schematic view illustrating an embodiment of an IHS.

FIG. 2a is a top perspective view illustrating an embodiment of an air directing apparatus.

FIG. 2b is a cut-away perspective view illustrating an embodiment of the air directing apparatus of FIG. 2a.

FIG. 2c is a bottom perspective view illustrating an embodiment of the air directing apparatus of FIG. 2a.

FIG. 2d is a cross sectional view illustrating an embodiment of the air directing apparatus of FIG. 2a.

FIG. 2e is a front view illustrating an embodiment of the air directing apparatus of FIG. 2a with the baffle members moved into the component housing.

FIG. 2f is a front view illustrating an embodiment of the air directing apparatus of FIG. 2a with the baffle members moved out of the component housing.

FIG. 3a is a perspective view illustrating an embodiment of a board used with the air directing apparatus of FIGS. 2a, 2b, 2c, 2d, 2e and 2f.

FIG. 3b is a front view illustrating an embodiment of components and connectors on the board of FIG. 3a.

FIG. 4a is a flow chart illustrating an embodiment of a method for directing air in a chassis.

FIG. 4b is a perspective view illustrating an embodiment of the air directing apparatus of FIGS. 2a, 2b, 2c, 2d, 2e and 2f being coupled to the board of FIGS. 3a and 3b.

FIG. 4c is a perspective view illustrating an embodiment of the air directing apparatus of FIGS. 2a, 2b, 2c, 2d, 2e and 2f coupled to the board of FIGS. 3a and 3b.

FIG. 4d is a cut away perspective view illustrating an embodiment of the air directing apparatus of FIGS. 2a, 2b, 2c, 2d, 2e and 2f coupled to the board of FIGS. 3a and 3b.

FIG. 4e is a cross sectional view illustrating an embodiment of the air directing apparatus of FIGS. 2a, 2b, 2c, 2d, 2e and 2f coupled to the board of FIGS. 3a and 3b.

FIG. 4f is a front view illustrating an embodiment of the air directing apparatus of FIGS. 2a, 2b, 2c, 2d, 2e and 2f coupled to the board of FIGS. 3a and 3b.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

In one embodiment, IHS 100, FIG. 1, includes a processor 102, which is connected to a bus 104. Bus 104 serves as a connection between processor 102 and other components of computer system 100. An input device 106 is coupled to processor 102 to provide input to processor 102. Examples of input devices include keyboards, touchscreens, and pointing devices such as mouses, trackballs and trackpads. Programs and data are stored on a mass storage device 108, which is coupled to processor 102. Mass storage devices include such devices as hard disks, optical disks, magneto-optical drives, floppy drives and the like. IHS system 100 further includes a display 110, which is coupled to processor 102 by a video controller 112. A system memory 114 is coupled to processor 102 to provide the processor with fast storage to facilitate execution of computer programs by processor 102. In an embodiment, a chassis 116 houses some or all of the components of IHS 100. It should be understood that other buses and intermediate circuits can be deployed between the components described above and processor 102 to facilitate interconnection between the components and the processor 102.

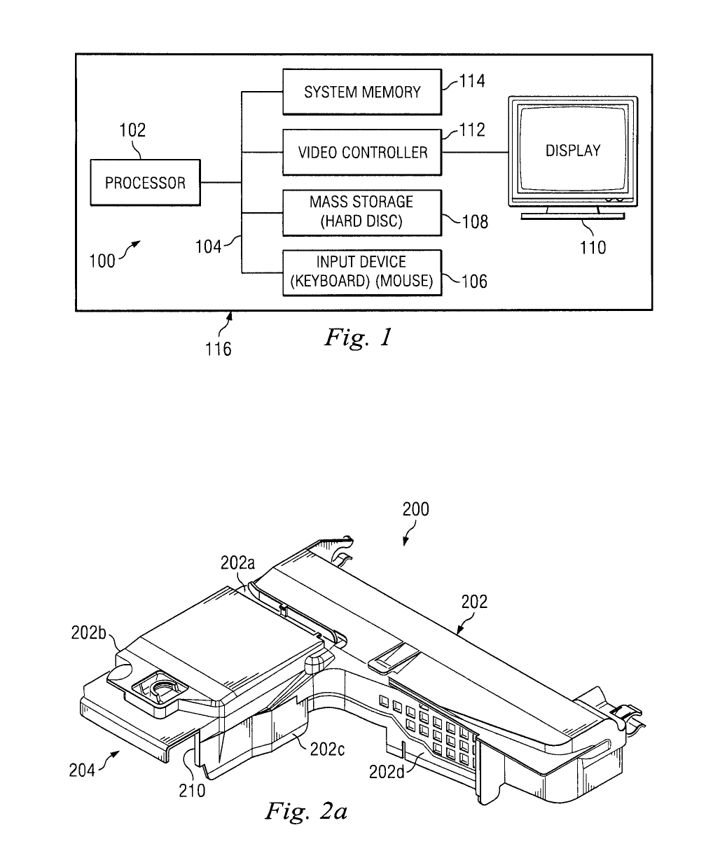

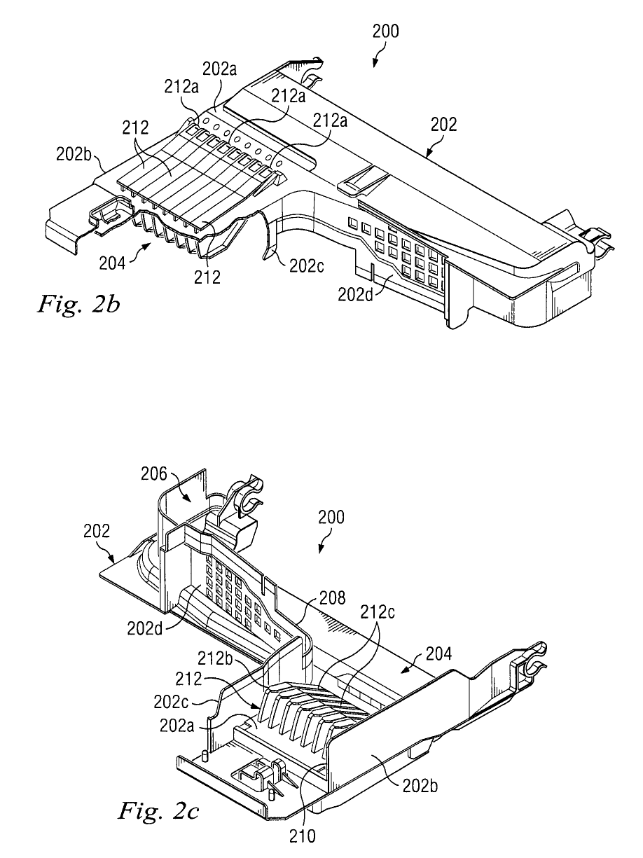

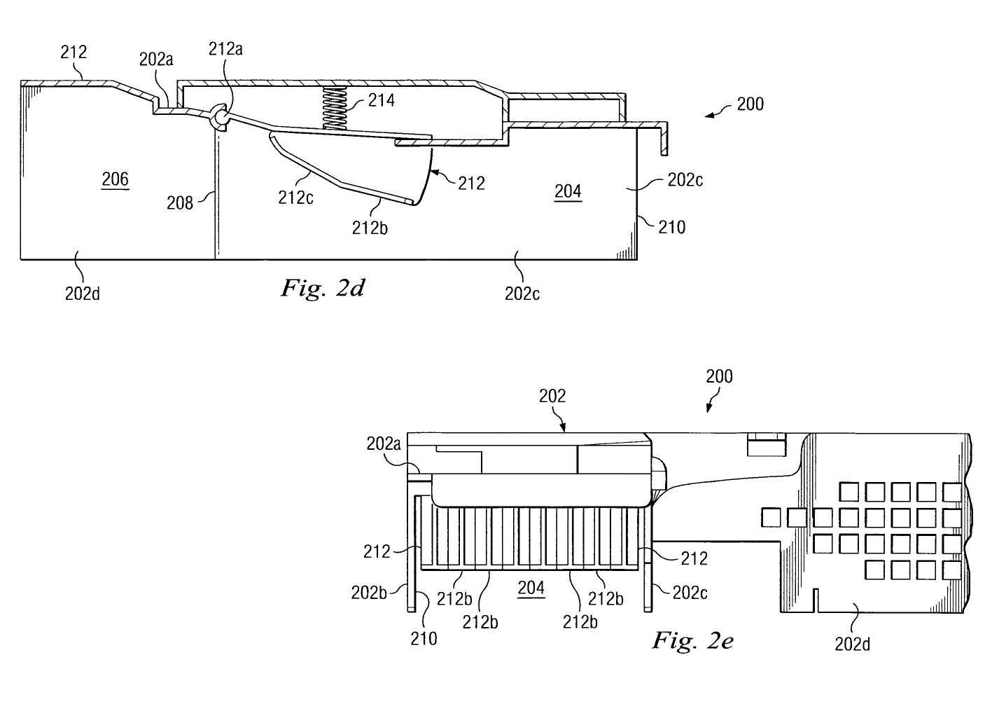

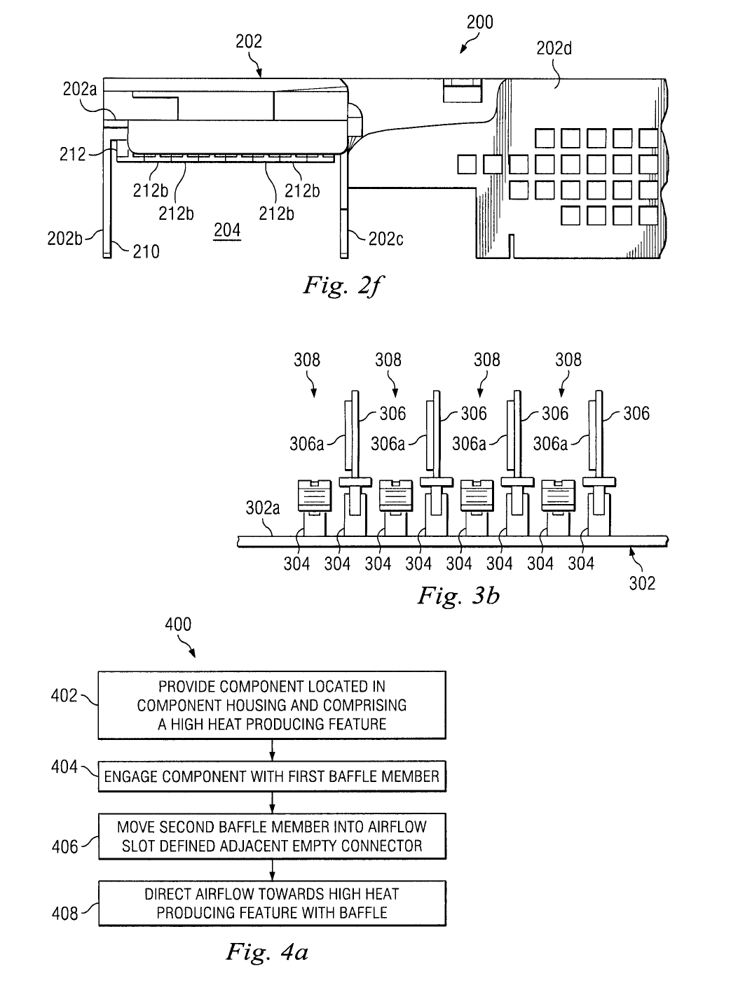

Referring now to FIGS. 2a, 2b, 2c, 2d, 2e and 2f, an air directing apparatus 200 is illustrated. The air directing apparatus 200 includes a base 202 having a top wall 202a. A plurality of side walls 202b and 202c extend from the top wall 202a in a spaced apart orientation from each other such that they define a component housing 204 between themselves and the top wall 202a. A secondary side wall 202d extends from the top wall 202a and the side wall 202c and is located adjacent an edge of the top wall 202a opposite the side wall 202b. A heat sink housing 206 is defined between the top wall 202a, the side wall 202b, and the secondary side wall 202d. An air entrance 208 is defined by the top wall 202a and the side walls 202b and 202c and is located between the heat sink housing 206 and the component housing 204. An air exit 210 is defined by the top wall 202a and the side walls 202b and 202c and is located opposite the component housing 204 from the air entrance 208. A plurality of baffle members 212 are each moveably coupled to the base 202 on a pivotal coupling 212a such that each baffle member 212 may independently move into and out of the component housing 204, illustrated in FIGS. 2e and 2f. Each baffle member 212 includes a component engagement surface 212b and an air directing member 212c located adjacent the component engagement surface 212b. In an embodiment, the air directing member 212c may be, for example, a surface oriented at an angle relative to the component engagement surface 212b, as illustrated. Each baffle member 212 may be resiliently biased into the component housing 204 by a resilient member 214, as illustrated.

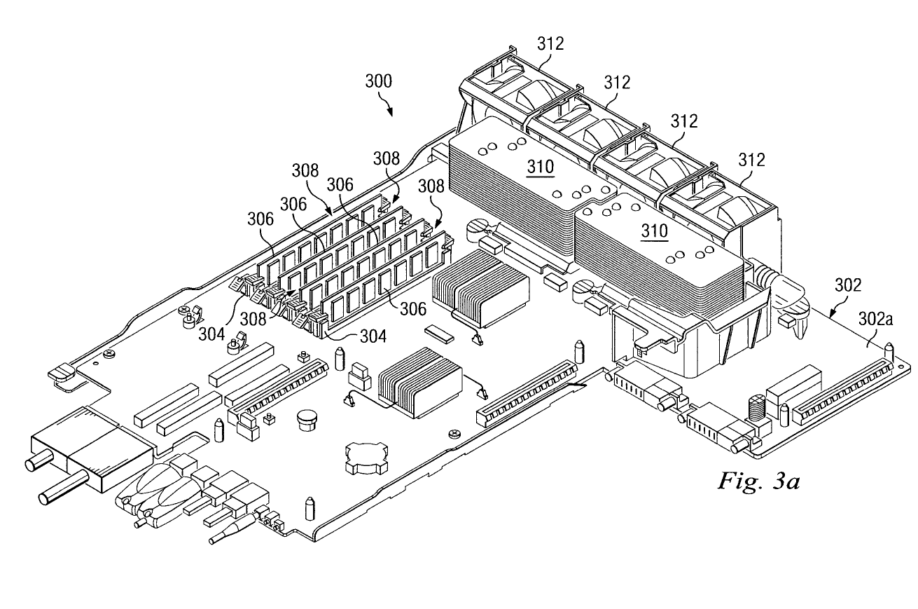

Referring now to FIGS. 3a and 3b, a board 300 is illustrated. In an embodiment, the board 300 may be located in an IHS chassis such as, for example, the chassis 116, described above with reference to FIG. 1, and may include some or all of the components of the IHS 100, described above with reference to FIG. 1. The board 300 includes a base 302 having a top surface 302a. A plurality of component connectors 304 are mounted to the top surface 302a of the base 302 in a substantially parallel and spaced apart orientation. A plurality of components 306 are coupled to some of the component connectors 304, each component 306 including a high heat producing feature 306a on the component 306. In an embodiment, the components 306 may be memory devices such as, for example, DIMMs, and the high heat producing features may be, for example, AMBs. A plurality of airflow slots 308 are defined adjacent the connectors 304 that do not have components 304 coupled to them. A plurality of heat sinks 310 are coupled to the top surface 302a of the base 302 and are located adjacent the connectors 304. In an embodiment, the heat sinks 310 may be thermally coupled to a plurality of processors which may be, for example, the processor 102, described above with reference to FIG. 1. A plurality of fans 312 are coupled to the top surface 302a of the base 302 and are located adjacent the heat sinks 310.

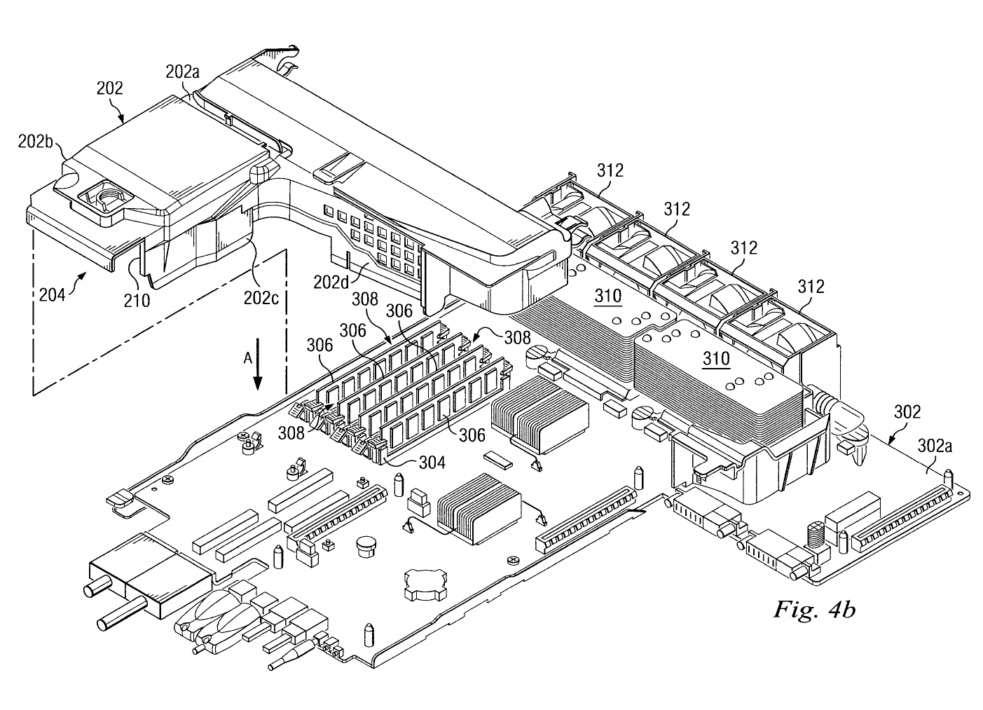

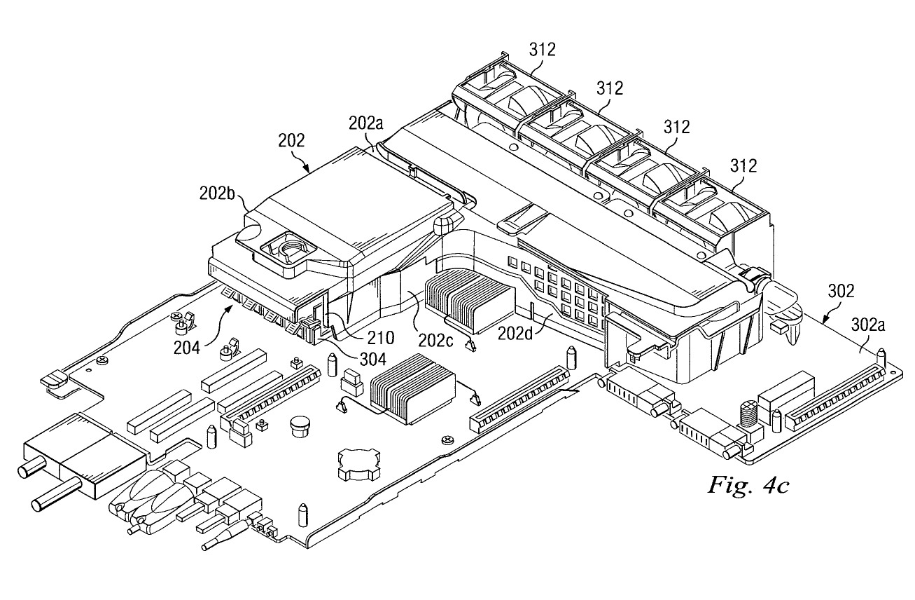

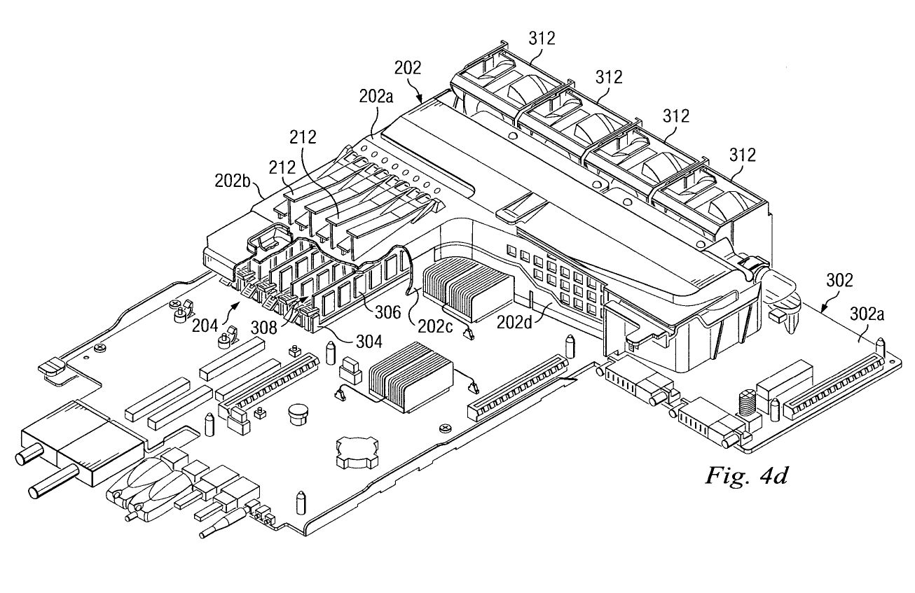

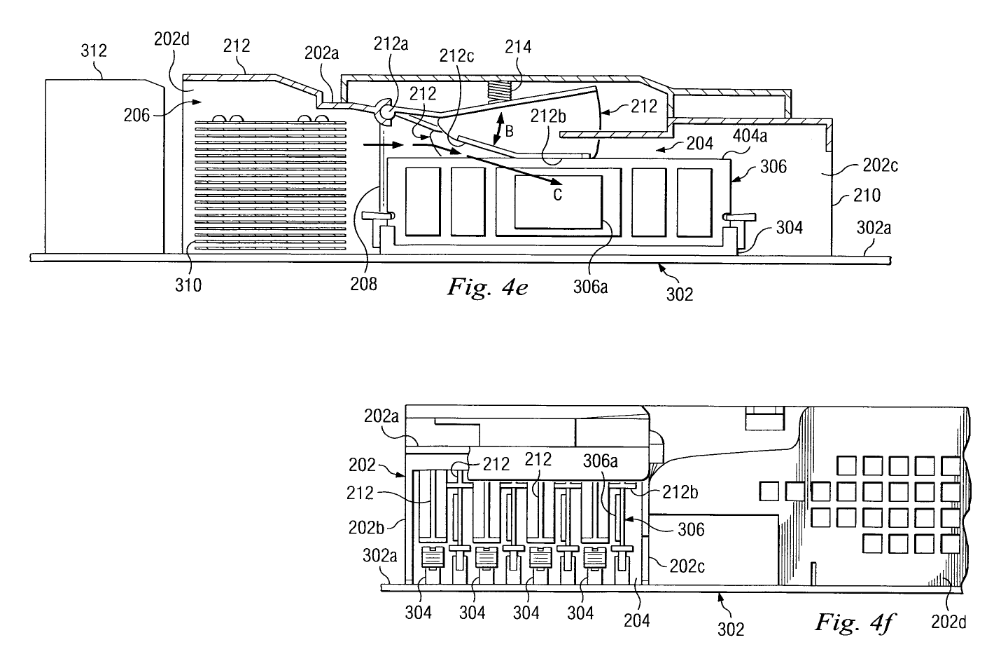

Referring now to FIGS. 2a, 2b, 2c, 2d, 2e, 2f, 3a, 3b, 4a, 4b, 4c, 4d, 4e and 4f, a method 400 for directing airflow in a chassis is illustrated. The method 400 begins at step 402 where a component located in a component housing and comprising a high heat producing feature is provided. The board 300, described above with reference to FIGS. 3a and 3b, is provided and the air directing apparatus 200, described above with reference to FIGS. 2a, 2b, 2c, 2d, 2e and 2f, is positioned adjacent the board 300 such that the component housing 204 defined by the air directing apparatus 200 is located adjacent the components 306 on the board 300 and the heat sink housing 206 is located adjacent the heat sinks 310 on the board, as illustrated in FIG. 4b. The air directing apparatus 200 is then moved in a direction A such that the side walls 202b and 202c and the second secondary side wall 202d engage the top surface 302a on the base 302 of the board 300 to couple the air directing apparatus 200 to the board 300, as illustrated in FIG. 4c. In an embodiment, the side walls 202b and 202c and the secondary side wall 202d include features which allow the air directing apparatus 200 to be secured to the board 300. With the air directing apparatus 200 coupled to the board 300, the components 306 are positioned in the component housing 204 defined by the air directing apparatus 200 and the heat sinks 310 are positioned in the heat sink housing 206 defined by the air directing apparatus 200. The method 400 then proceeds to step 404 of the method where a component is engaged with a first baffle member. As the air directing apparatus 200 is moved in the direction A to couple the air directing apparatus 200 to the board 300, some of the baffle members 212 are located adjacent the connectors 304 with components 306 in them. The component engagement surface 212b on the baffle members 212 located adjacent the connectors 304 with components 306 in them engages a first surface 404a on the components 212 such that those baffle members 212 are moved out of the component housing 204 and an acute angle B is formed between the air directing member 212c and the first surface 404a of the component 306, as illustrated in FIGS. 4e and 4f. The method 400 then proceeds to step 406 where a second baffle member is moved into the airflow slot defined adjacent an empty connector. As the air directing apparatus 200 is moved in the direction A to couple the air directing apparatus 200 to the board 300, some of the baffle members 212 are located adjacent the airflow slots 308 defined adjacent the connectors 304 without components 306 in them. The baffle members 212 which are located adjacent the airflow slots 308 defined adjacent the connectors 304 without components 306 in them enter the airflow channels 308 such that the component engagement surface 212b is located adjacent the connector 304, as illustrated in FIG. 4f. The method 400 then proceeds to step 408 where airflow is directed towards a high heat producing feature with an air directing member. When the fans 312 on the board 300 are operated, airflow from the fans 312 enters the heat sink housing 206 defined by the air directing apparatus 200 and is directed towards the air entrance 208 adjacent the component housing 204. The baffle members 212 located in the airflow slots 308 impede airflow through those airflow slots 308 and direct the airflow past the components 306. As the airflow is directed past the components 306, the airflow is directed along a path C by the air directing member 212c, as illustrated in FIG. 4e. The air directing member 212c is designed such that the path C directs airflow at the high heat producing features 306a on the components 306 in order to provide the high heat feature additional cooling. Due to the baffle members 212 being moveable through the component housing 204, the baffle members 212 are operable to engage components of different sizes and heights in order to optimize airflow through the component housing 204. Thus, a method and apparatus are provided that direct air in a chassis to optimize that airflow to flow only to areas that include components and further optimizes that airflow towards high heat producing features on those components.

In an experimental embodiment, Fully Buffered Dual Inline Memory Modules (FB DIMMs) with AMBs were used as the components 306 with high heat producing features 306a, respectively. It was found that the performance of the FB DIMMs was limited by the ability to provide temperature control for the AMBs on the FB DIMMs, and that the nature of the systems memory management produced higher temperatures in the FB DIMMs when some of the connectors 304 were empty. The air directing apparatus 200 provided a 5% AMB supported power increase and a 16% increase in airflow over the FB DIMMs.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. An air directing apparatus, comprising:
a base defining a component housing;
a baffle member moveably coupled to the base and movable into and out of the component housing such that the baffle member may engage a component located in the component housing; and
an air directing member located on the baffle member, whereby the air directing member directs an airflow towards a high heat producing feature on the component when the baffle member engages the component.

2. The apparatus of claim 1, wherein the base comprises an air shroud having an air entrance and an air exit located on opposite sides of the component housing.

3. The apparatus of claim 1, wherein the baffle member is resiliently biased into the component housing.

4. The apparatus of claim 1, wherein the baffle member is pivotally coupled to the base.

5. The apparatus of claim 1, wherein the component housing defines an airflow slot, whereby the baffle member is operable to move into and out of the component housing such that the baffle member may impede airflow through the airflow slot.

6. The apparatus of claim 1, wherein the baffle member is operable to engage a first surface on the component, whereby the air directing member is orientated at an acute angle relative to the first surface when the baffle member engages the component.

7. The apparatus of claim 1, further comprising:
a plurality of baffle members moveably coupled to the base and operable to move into and out of the component housing, wherein the plurality of baffle members are located adjacent each other and are each independently moveably coupled to the base such that each baffle member may engage a component located in the component housing.

8. The apparatus of claim 7, wherein each of the plurality of baffle members is resiliently biased into the component housing.

9. An information handling system, comprising:
a board;
a processor mounted to the board;
a fan coupled to the board;
a first component connector mounted to the board and electrically coupled to the processor;
a component coupled to the first component connector and comprising a high heat producing feature;
a base coupled to the board and defining a component housing, whereby the first component connector and the component are located in the component housing;
a first baffle member moveably coupled to the base and operable to move into and out of the component housing, whereby the first baffle member engages the component; and
an air directing member located on the first baffle member, whereby the air directing member is operable to direct an airflow from the fan towards the high heat producing feature on the component.

10. The system of claim 1, wherein the base comprises an air shroud having an air entrance and an air exit located on opposite sides of the component housing, whereby the fan is located adjacent the air entrance.

11. The system of claim 1, wherein the first baffle member is resiliently biased into the component housing.

12. The system of claim 1, wherein the first baffle member is pivotally coupled to the base.

13. The system of claim 1, further comprising:
a plurality of the baffle members moveably coupled to the base and operable to move into and out of the component housing, wherein the component housing defines an airflow slot, whereby at least one baffle member is located in the airflow slot defined by the component housing such that the at least one baffle member impedes airflow through the airflow slot.

14. The system of claim 1, wherein the baffle member engages a first surface on the component, whereby the air directing member is orientated at an acute angle relative to the first surface.

15. The system of claim 1, further comprising:
a second component connector mounted to the board adjacent the first component connector in the component housing and electrically coupled to the processor, whereby an airflow slot is defined adjacent the second component connector;
a second baffle member moveably coupled to the base and located in the airflow slot.

16. The system of claim 1, wherein the component is a Dual Inline Memory Module (DIMM).

17. The system of claim 1, wherein the high heat producing feature is an Advanced Memory Buffer.

18. A method for directing airflow in a chassis comprising:
providing a component located in a component housing defined by a chassis and comprising a high heat producing feature;
engaging the component with a first baffle member that is operable to move into and out of the component housing; and
directing airflow from a fan towards the high heat producing feature on the component with an air directing member on the first baffle member

19. The method of claim 18, further comprising:
providing an airflow slot defined by the chassis and located adjacent the component; and
moving a second baffle member into the airflow slot such that the second baffle member impedes airflow from a fan through the airflow slot.

20. The method of claim 18, wherein the directing airflow from a fan comprises forming an acute angle between the air directing member on the first baffle member and a first surface located on the component that is engaged by the first baffle member.
